(19) United States
(12) Patent Application Publication
(10) Pub. No.: US 2023/0389339 A1
(43) Pub. Date: Nov. 30, 2023

(54) SEMICONDUCTOR STRUCTURE AND METHOD FOR FORMING THE SAME

(71) Applicant: CHANGXIN MEMORY TECHNOLOGIES, INC., Hefei City (CN)

(72) Inventor: Chao LIN, Hefei City (CN)

(73) Assignee: CHANGXIN MEMORY TECHNOLOGIES, INC., Hefei City (CN)

(21) Appl. No.: 18/169,839

(22) Filed: Feb. 15, 2023

Related U.S. Application Data
(63) Continuation of application No. PCT/CN2022/101127, filed on Jun. 24, 2022.

(30) Foreign Application Priority Data
May 30, 2022 (CN) 202210603709.5

(51) Int. Cl. H10B 80/00; H01L 23/00

(52) U.S. Cl. CPC H10B 80/00; H01L 24/02; H01L 24/80; H01L 24/06; H01L 24/05; H01L 24/08; H01L 2224/0231; H01L 2224/02373; H01L 2224/02381; H01L 2224/02375; H01L 2224/0239; H01L 2924/01029; H01L 2924/01013; H01L 2924/0132; H01L 2924/01074; H01L 2224/05018; H01L 2224/05026; H01L 2224/05166; H01L 2224/05184; H01L 2224/05181; H01L 2224/05169; H01L 2224/05186; H01L 2924/04941; H01L 2224/05647; H01L 2224/05624; H01L 2224/05684; H01L 2224/05571; H01L 2224/80357; H01L 2224/8001; H01L 2224/80895; H01L 2224/06158; H01L 2224/08145; H01L 2924/1431; H01L 2924/1436

(57) ABSTRACT

A semiconductor structure includes a first semiconductor layer and a second semiconductor layer bonded to each other. The first semiconductor layer includes a first redistribution line, and the first redistribution line has a first projection length on a bonding surface of the first semiconductor layer and the second semiconductor layer. The second semiconductor layer includes a second redistribution line, and the second redistribution line has a second projection length on the bonding surface. The first projection length is different from the second projection length. The first redistribution line is electrically connected to the second redistribution line. A method for forming the same is also provided.

### CROSS-REFERENCE TO RELATED APPLICATIONS

This is a continuation of International Patent Application No. PCT/CN2022/101127 filed on Jun. 24, 2022, which claims priority to Chinese Patent Application No. 202210603709.5 filed on May 30, 2022. The disclosures of the above-referenced applications are hereby incorporated by reference in their entirety.

### BACKGROUND

In a current three-dimensional (3D) semiconductor structure technology, stacks of wafers are usually connected by using contact holes. However, deviations easily occur when the contact holes are etched, which leads to misalignment of electrical connection points between two wafers and makes it impossible to realize an effective electrical connection between the wafers. Furthermore, when two wafers are connected through the contact holes, a parasitic capacitance is large due to a small distance between the contact holes, which easily leads to a delay of Resistor-Capacitance (RC) circuit.

### SUMMARY

The disclosure relates to the technical field of semiconductors, and relates to, but is not limited to a semiconductor structure and a method for forming the same.

In view of this, embodiments of the disclosure provide a semiconductor structure and a method for forming the same.

According to a first aspect of the disclosure, there is provided a semiconductor structure, including a first semiconductor layer and a second semiconductor layer bonded to each other.

The first semiconductor layer includes a first redistribution line, and the first redistribution line has a first projection length on a bonding surface of the first semiconductor layer and the second semiconductor layer.

The second semiconductor layer includes a second redistribution line, and the second redistribution line has a second projection length on the bonding surface. The first projection length is different from the second projection length.

The first redistribution line is electrically connected to the second redistribution line.

In some embodiments, the first semiconductor layer may include multiple first redistribution lines, and the second semiconductor layer may include multiple second redistribution lines. Projection lengths of any two adjacent first redistribution lines on the bonding surface are different, or projection lengths of any two adjacent second redistribution lines on the bonding surface are different.

In some embodiments, each of the multiple first redistribution lines may be electrically connected to a respective one of the multiple second redistribution lines, and a sum of projection lengths of each of the multiple first redistribution lines and a respective one of the multiple second redistribution lines on the bonding surface has a same value.

In some embodiments, the multiple first redistribution lines may be circularly arranged in a preset arrangement manner.

The preset arrangement manner includes first projection lengths of the multiple first redistribution lines being sequentially increased, the first projection lengths being sequentially decreased, the first projection lengths being firstly increased and then decreased, and the first projection lengths being firstly decreased and then increased.

In some embodiments, as the first projection lengths of the multiple first redistribution lines on the bonding surface are sequentially decreased, second projection lengths of the multiple second redistribution lines corresponding to the multiple first redistribution lines on the bonding surface may be sequentially increased.

In some embodiments, as the first projection lengths of the multiple first redistribution lines on the bonding surface are sequentially increased, second projection lengths of the multiple second redistribution lines corresponding to the multiple first redistribution lines on the bonding surface may be sequentially decreased.

In some embodiments, as the first projection lengths of the multiple first redistribution lines on the bonding surface are firstly increased and then decreased, second projection lengths of the multiple second redistribution lines corresponding to the multiple first redistribution lines on the bonding surface may be firstly decreased and then increased.

In some embodiments, as the first projection lengths of the multiple first redistribution lines on the bonding surface are firstly decreased and then increased, second projection lengths of the multiple second redistribution lines corresponding to the multiple first redistribution lines on the bonding surface may be firstly increased and then decreased.

In some embodiments, the first semiconductor layer may further include a first metal pad connected to the first redistribution line, and the second semiconductor layer may further include a second metal pad connected to the second redistribution line.

The first redistribution line is electrically connected to the second redistribution line through the first metal pad and the second metal pad.

In some embodiments, each of multiple first metal pads may be bonded with a respective one of multiple second metal pads to form a respective one of multiple bonding pads, and the multiple bonding pads are distributed in a ladder shape on the bonding surface.

In some embodiments, the first semiconductor layer may include a memory array, and the memory array may include multiple wordlines and multiple bitlines.

Each of the multiple wordlines is electrically connected to a respective one of the multiple first redistribution lines, and each of the multiple bitlines is electrically connected to a respective one of the multiple first redistribution lines.

In some embodiments, the second semiconductor layer may include a peripheral circuit, and the multiple second redistribution lines may be electrically connected to the peripheral circuit.

In some embodiments, each of the multiple wordlines may be electrically connected to the peripheral circuit through a respective one of the multiple first redistribution lines and a respective one of the multiple second redistribution lines, and each of the multiple bitlines may be electrically connected to the peripheral circuit through a respective one of the multiple first redistribution lines and a respective one of the multiple second redistribution lines.

In some embodiments, the first semiconductor layer may include a first dielectric layer, and the multiple first redistribution lines may be located within the first dielectric layer. The second semiconductor layer may include a second dielectric layer, and the multiple second redistribution lines may be located within the second dielectric layer. The semiconductor structure may further include a barrier layer.

The barrier layer is located between the multiple first redistribution lines and the first dielectric layer, between the multiple second redistribution lines and the second dielectric layer, between the multiple bonding pads and the first dielectric layer, and between the multiple bonding pads and the second dielectric layer.

According to a second aspect of the disclosure, there is provided a method for forming a semiconductor structure, including the following operations.

A first semiconductor layer and a second semiconductor layer are provided.

A first redistribution line is formed in the first semiconductor layer. The first redistribution line has a first projection length on a bonding surface of the first semiconductor layer and the second semiconductor layer.

A second redistribution line is formed in the second semiconductor layer. The second redistribution line has a second projection length on the bonding surface, and the first projection length is different from the second projection length.

The first semiconductor layer is bonded with the second semiconductor layer to electrically connect the first redistribution line to the second redistribution line.

In some embodiments, the first redistribution line may be formed by the following operations.

A first dielectric layer is formed on a surface of a substrate of the first semiconductor layer.

The first dielectric layer is etched to form a first etching trench.

The first etching trench is filled with metal material to form the first redistribution line.

In some embodiments, the second redistribution line may be formed by the following operations.

A second dielectric layer is formed on a surface of a substrate of the second semiconductor layer.

The second dielectric layer is etched to form a second etching trench.

The second etching trench is filled with metal material to form the second redistribution line.

In some embodiments, the method may further include the following operations. A first metal pad electrically connected to the first redistribution line is formed. A second metal pad electrically connected to the second redistribution line is formed.

In some embodiments, the operation of bonding the first semiconductor layer with the second semiconductor layer to electrically connect the first redistribution line to the second redistribution line may include the following operations.

Surface activation treatment is performed on a first surface of the first semiconductor layer exposing the first metal pad and a second surface of the second semiconductor layer exposing the second metal pad.

The first surface is attached to the second surface with the first metal pad being aligned to the second metal pad face to face.

The first semiconductor layer and the second semiconductor layer are annealed.

According to the semiconductor structure and the method for forming the same provided in the embodiments of the disclosure, the semiconductor includes a first semiconductor layer and a second semiconductor layer bonded to each other. The first semiconductor layer includes a first redistribution line, and the first redistribution line has a first projection length on a bonding surface of the first semiconductor layer and the second semiconductor layer. The second semiconductor layer includes a second redistribution line, and the second redistribution line has a second projection length on the bonding surface. The first projection length is different from the second projection length. The first redistribution line is electrically connected to the second redistribution line. In the embodiments of the disclosure, semiconductor layers are electrically connected by bonding.

### BRIEF DESCRIPTION OF THE DRAWINGS

In the drawings (which are not necessarily drawn to scale), like reference numerals may represent like components in different views. Like reference numerals with different letter suffixes may denote different examples of like components. The drawings generally illustrate the embodiments discussed herein by way of example rather than limitation.

FIG. 1A is a schematic structural diagram of a semiconductor structure according to an embodiment of the disclosure.

FIG. 1B is a schematic diagram of projections of multiple bonding pads on a bonding surface of a first semiconductor layer and a second semiconductor layer according to an embodiment of the disclosure.

FIG. 2A is a first schematic diagram of projections of first redistribution lines and second redistribution lines on a bonding surface of a first semiconductor layer and a second semiconductor layer according to an embodiment of the disclosure.

FIG. 2B is a second schematic diagram of projections of first redistribution lines and second redistribution lines on a bonding surface of a first semiconductor layer and a second semiconductor layer according to an embodiment of the disclosure.

FIG. 2C is a third schematic diagram of projections of first redistribution lines and second redistribution lines on a bonding surface of a first semiconductor layer and a second semiconductor layer according to an embodiment of the disclosure.

FIG. 2D is a fourth schematic diagram of projections of first redistribution lines and second redistribution lines on a bonding surface of a first semiconductor layer and a second semiconductor layer according to an embodiment of the disclosure.

FIG. 3 is a schematic structural diagram of another semiconductor structure according to an embodiment of the disclosure.

FIG. 4 is a schematic flowchart of a method for forming a semiconductor structure according to an embodiment of the disclosure.

FIG. 5A is a first schematic diagram of a process for forming a semiconductor structure according to an embodiment of the disclosure.

FIG. 5B is a second schematic diagram of a process for forming a semiconductor structure according to an embodiment of the disclosure.

FIG. 5C is a third schematic diagram of a process for forming a semiconductor structure according to an embodiment of the disclosure.

FIG. 5D is a fourth schematic diagram of a process for forming a semiconductor structure according to an embodiment of the disclosure.

FIG. 5E is a fifth schematic diagram of a process for forming a semiconductor structure according to an embodiment of the disclosure.

FIG. 5F is a sixth schematic diagram of a process for forming a semiconductor structure according to an embodiment of the disclosure.

FIG. 5G is a seventh schematic diagram of a process for forming a semiconductor structure according to an embodiment of the disclosure.

FIG. 5H is an eighth schematic diagram of a process for forming a semiconductor structure according to an embodiment of the disclosure.

FIG. 5I is a ninth schematic diagram of a process for forming a semiconductor structure according to an embodiment of the disclosure.

FIG. 5J is a tenth schematic diagram of a process for forming a semiconductor structure according to an embodiment of the disclosure.

FIG. 5K is an eleventh schematic diagram of a process for forming a semiconductor structure according to an embodiment of the disclosure.

FIG. 5L is a twelfth schematic diagram of a process for forming a semiconductor structure according to an embodiment of the disclosure.

### DESCRIPTION OF REFERENCE NUMERALS

10: bonding surface;

11: first semiconductor layer;

111/111a/111b/111c/111d/111e: first redistribution line;

12: second semiconductor layer;

121/121a/121b/121c/121d/121e: second redistribution line;

1111: first wiring;

1112: second wiring;

1113: third wiring;

1211: fourth wiring;

1212: fifth wiring;

1213: sixth wiring;

112: first dielectric layer;

122: second dielectric layer;

1121: first initial dielectric layer;

1122: second initial dielectric layer;

1123: third initial dielectric layer;

1124: fourth initial dielectric layer;

1221: fifth initial dielectric layer;

1222: sixth initial dielectric layer;

1223: seventh initial dielectric layer;

1224: eighth initial dielectric layer;

13/13a/13b/13c/13d/13e/13f/13g/13h/13i/13j: bonding pad;

131: first metal pad;

132: second metal pad;

14: memory array;

141: wordline;

142: capacitance;

143: support structure;

15: peripheral circuit;

151: active area;

16: barrier layer;

161: first barrier layer;

162: second barrier layer;

163: third barrier layer;

164: fourth barrier layer;

165: fifth barrier layer;

166: sixth barrier layer;

167: seventh barrier layer;

168: eighth barrier layer;

17: substrate;

100/200: semiconductor structure.

### DETAILED DESCRIPTION

In order to make purpose, technical solutions and advantages of the embodiments of the disclosure more clear, specific technical solutions of the disclosure would be further described in detail below in combination with the drawings in the embodiments of the disclosure. The following embodiments are intended to explain the disclosure, but are not intended to limit the scope of the disclosure.

Based on the problems existed in some implementations, the embodiments of the disclosure provide a semiconductor structure and a method for forming the same, which will be further described in detail below in combination with the drawings.

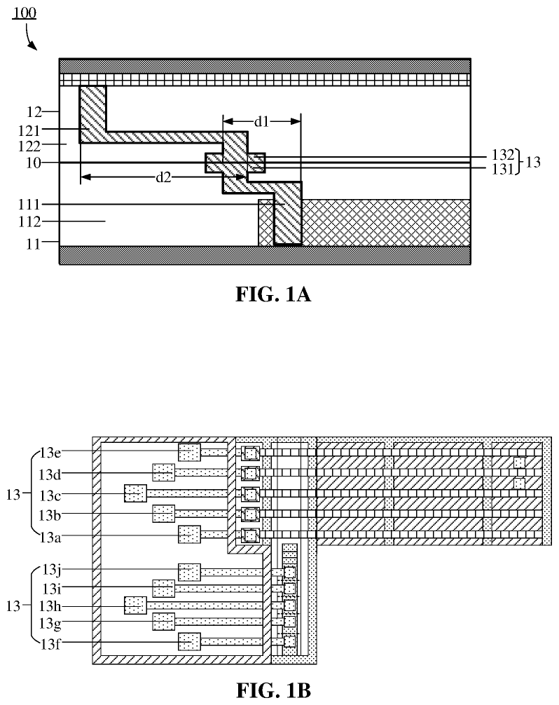

FIG. 1A is a schematic structural diagram of a semiconductor structure according to an embodiment of the disclosure. As illustrated in FIG. 1A, the semiconductor structure 100 includes a first semiconductor layer 11 and a second semiconductor layer 12 bonded to each other. The first semiconductor layer 11 includes a first redistribution line 111, and the first redistribution line 111 has a first projection length d1 on a bonding surface 10 of the first semiconductor layer 11 and the second semiconductor layer 12. The second semiconductor layer 12 includes a second redistribution line 121, and the second redistribution line 121 has a second projection length d2 on the bonding surface 10. The first projection length d1 is different from the second projection length d2. The first redistribution line 111 is electrically connected to the second redistribution line 121.

In the embodiment of the disclosure, the first semiconductor layer 11 and the second semiconductor layer 12 may be wafers or chips obtained after wafer dicing. A bonding manner of the first semiconductor layer 11 and the second semiconductor layer 12 may include direct bonding, hot pressing bonding, plasma activated bonding, bonding agent bonding, or the like.

In the embodiment of the disclosure, the first semiconductor layer 11 may further include a first dielectric layer 112, and the first redistribution line 111 is located within the first dielectric layer 112. The second semiconductor layer 12 may further include a second dielectric layer 122, and the second redistribution line 121 is located within the second dielectric layer 122. The first redistribution line 111 and the second redistribution line 121 may be composed of any one of conductive metal materials such as copper, aluminum, copper-aluminum alloy or tungsten. Materials of the first dielectric layer 112 and the second dielectric layer 122 may be oxides such as silicon oxide.

With continued reference to FIG. 1A, the first semiconductor layer 11 may further include a first metal pad 131 connected to the first redistribution line 111, and the second semiconductor layer 12 may further include a second metal pad 132 connected to the second redistribution line 121. The first redistribution line 111 is electrically connected to the second redistribution line 121 through the first metal pad 131 and the second metal pad 132.

In the embodiment of the disclosure, the first metal pad 131 is bonded with the second metal pad 132 to form a bonding pad 13, and multiple bonding pads 13 are distributed in a ladder shape on the bonding surface 10.

FIG. 1B is a schematic diagram of projections of multiple bonding pads on a bonding surface of a first semiconductor layer and a second semiconductor layer according to an embodiment of the disclosure. As illustrated in FIG. 1B, in the embodiment of the disclosure, bonding pads 13a, 13b, 13c, 13d and 13e are distributed in a ladder shape on the bonding surface 10 of the first semiconductor layer 11 and the second semiconductor layer 12. Bonding pads 13f, 13g, 13h, 13i and 13j are also distributed in a ladder shape on the bonding surface of the first semiconductor layer 11 and the second semiconductor layer 12.

In the embodiment of the disclosure, the bonding pads are distributed in a ladder shape on the bonding surface of the first semiconductor layer 11 and the second semiconductor layer 12, which may include at least one of the following distribution manners: distances between the bonding pads 13a, 13b, 13c, 13d, 13e and a memory array being sequentially increased, these distances being sequentially decreased, these distances being firstly increased and then decreased, or these distances being firstly decreased and then increased.

In the embodiment of the disclosure, semiconductor layers are electrically connected by bonding. Since metal pads used for bonding have large areas, a problem of an electric connection failure between two semiconductor layers which is caused by a misalignment due to small electric connection points between the two semiconductor layers, may be avoided, thereby improving yield rate of semiconductor manufacturing. Furthermore, in the embodiment of the disclosure, a distance between the bonding pads may be increased by providing different projection lengths of redistribution lines in two semiconductor layers, thereby reducing a parasitic capacitance and improving performance of the semiconductor structure.

In some embodiments, each of multiple first redistribution lines 111 is electrically connected to a respective one of multiple second redistribution lines 121, and a sum of projection lengths of each of the multiple first redistribution lines 111 and a respective one of the multiple second redistribution lines 121 on the bonding surface 10 has a same value.

In the embodiment of the disclosure, the multiple first redistribution lines 111 are circularly arranged in a preset arrangement manner. The preset arrangement manner includes at least one of the following manners: first projection lengths of the multiple first redistribution lines being sequentially increased, the first projection lengths being sequentially decreased, the first projection lengths being firstly increased and then decreased, or the first projection lengths being firstly decreased and then increased.

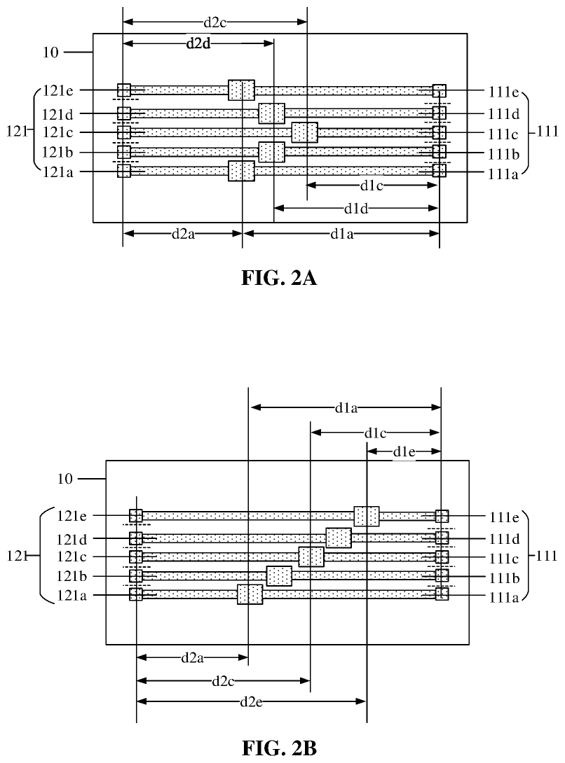

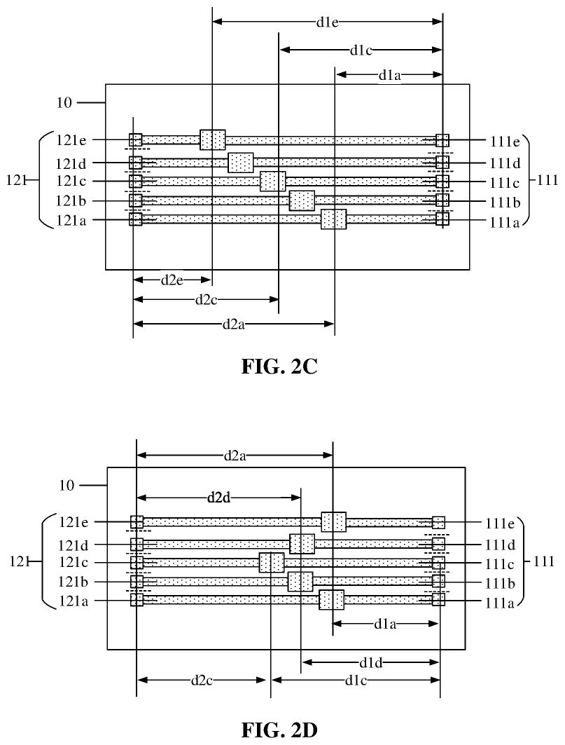

FIGS. 2A to 2D are schematic diagrams of projections of first redistribution lines and second redistribution lines on a bonding surface of a first semiconductor layer and a second semiconductor layer according to an embodiment of the disclosure. An arrangement manner of the first redistribution lines and the second redistribution lines on the bonding surface in the embodiment of the disclosure will be described in detail below with reference to FIGS. 2A to 2D.

In some embodiments, as the first projection lengths of the multiple first redistribution lines 111 on the bonding surface 10 are firstly decreased and then increased, second projection lengths of the multiple second redistribution lines 121 corresponding to the multiple first redistribution lines 111 on the bonding surface 10 are firstly increased and then decreased. As illustrated in FIG. 2A, the first redistribution lines 111a, 111b, 111c, 111d and 111e are respectively electrically connected to the second redistribution lines 121a, 121b, 121c, 121d and 121e in one-to-one correspondence. As the first projection lengths of the first redistribution lines 111a, 111c and 111d on the bonding surface 10 are firstly decreased (i.e. d1a>d1c) and then increased (i.e. d1c<d1d), the second projection lengths of the second redistribution lines 121a, 121c and 121d corresponding to the first redistribution lines on the bonding surface 10 are firstly increased (i.e. d2a<d2c) and then decreased (i.e. d2c>d2d). In the embodiments of the disclosure, a sum of projection lengths of the first redistribution line 111a and the second redistribution line 121a on the bonding surface 10 (i.e. d1a+d2a) is equal to a sum of projection lengths of the first redistribution line 111c and the second redistribution line 121c on the bonding surface 10 (i.e. d1c+d2c).

In some embodiments, as the first projection lengths of the multiple first redistribution lines 111 on the bonding surface 10 are sequentially decreased, second projection lengths of the multiple second redistribution lines 121 corresponding to the multiple first redistribution lines 111 on the bonding surface 10 are sequentially increased. As illustrated in FIG. 2B, the first redistribution lines 111a, 111b, 111c, 111d and 111e are respectively electrically connected to the second redistribution lines 121a, 121b, 121c, 121d and 121e in one-to-one correspondence. As the first projection lengths of the first redistribution lines 111a, 111c and 111e on the bonding surface 10 are sequentially decreased (i.e. d1a>d1c>d1e), the second projection lengths of the second redistribution lines 121a, 121c and 121e corresponding to the first redistribution lines on the bonding surface 10 are sequentially increased (i.e. d2a<d2c<d2e). In the embodiments of the disclosure, a sum of projection lengths of the first redistribution line 111a and the second redistribution line 121a on the bonding surface 10 (i.e. d1a+d2a) is equal to a sum of projection lengths of the first redistribution line 111e and the second redistribution line 121e on the bonding surface 10 (i.e. d1e+d2e).

In some embodiments, as the first projection lengths of the multiple first redistribution lines 111 on the bonding surface 10 are sequentially increased, second projection lengths of the multiple second redistribution lines 121 corresponding to the multiple first redistribution lines 111 on the bonding surface 10 are sequentially decreased. As illustrated in FIG. 2C, the first redistribution lines 111a, 111b, 111c, 111d and 111e are respectively electrically connected to the second redistribution lines 121a, 121b, 121c, 121d and 121e in one-to-one correspondence. As the first projection lengths of the first redistribution lines 111a, 111c and 111e on the bonding surface 10 are sequentially increased (i.e. d1a<d1c<d1e), the second projection lengths of the second redistribution lines 121a, 121c and 121e corresponding to the first redistribution lines on the bonding surface 10 are sequentially decreased (i.e. d2a>d2c>d2e).

In some embodiments, as the first projection lengths of the multiple first redistribution lines 111 on the bonding surface 10 are firstly increased and then decreased, second projection lengths of the multiple second redistribution lines 121 corresponding to the multiple first redistribution lines 111 on the bonding surface 10 are firstly decreased and then increased. As illustrated in FIG. 2D, the first redistribution lines 111a, 111b, 111c, 111d and 111e are respectively electrically connected to the second redistribution lines 121a, 121b, 121c, 121d and 121e in one-to-one correspondence. As the first projection lengths of the first redistribution lines 111a, 111c and 111d on the bonding surface 10 are firstly increased (i.e. d1a<d1c) and then decreased (i.e. d1c>d1d), the second projection lengths of the second redistribution lines 121a, 121c and 121d corresponding to the first redistribution lines on the bonding surface 10 are firstly decreased (i.e. d2a>d2c) and then increased (i.e. d2c<d2d).

In some embodiments, with continued reference to FIGS. 2A to 2D, the first semiconductor layer 11 includes multiple first redistribution lines 111, and projection lengths of any two adjacent first redistribution lines 111 on the bonding surface 10 are different. For example, the first semiconductor layer 11 includes the first redistribution lines 111a, 111b, 111c, 111d and 111e, and projection lengths of the first redistribution line 111a and the first redistribution line 111b on the bonding surface 10 are different, or, projection lengths of the first redistribution line 111c and the first redistribution line 111d on the bonding surface 10 are different. In the embodiments of the disclosure, when the projection lengths of any two adjacent first redistribution lines 111 on the bonding surface 10 are different, projection lengths of the second redistribution lines 121 corresponding to any two adjacent first redistribution lines 111 on the bonding surface 10 may be the same or different. For example, the projection lengths of the first redistribution line 111a and the first redistribution line 111b on the bonding surface 10 are different, and projection lengths of the second redistribution line 121a and the second redistribution line 121b on the bonding surface 10 are the same (not shown).

In some embodiments, with continued reference to FIGS. 2A to 2D, the second semiconductor layer 12 includes multiple second redistribution lines 121, and projection lengths of any two adjacent second redistribution lines 121 on the bonding surface 10 are different. For example, the second semiconductor layer 12 includes the second redistribution lines 121a, 121b, 121c, 121d and 121e, and projection lengths of the second redistribution line 121a and the second redistribution line 121b on the bonding surface 10 are different, or, projection lengths of the second redistribution line 121c and the second redistribution line 121d on the bonding surface 10 are different. In the embodiments of the disclosure, when the projection lengths of any two adjacent second redistribution lines 121 on the bonding surface 10 are different, projection lengths of the first redistribution lines 111 corresponding to any two adjacent second redistribution lines 121 on the bonding surface 10 may be the same or different. For example, the projection lengths of the second redistribution line 121a and the second redistribution line 121b on the bonding surface 10 are different, and projection lengths of the first redistribution line 111a and the first redistribution line 111b on the bonding surface 10 are the same (not shown).

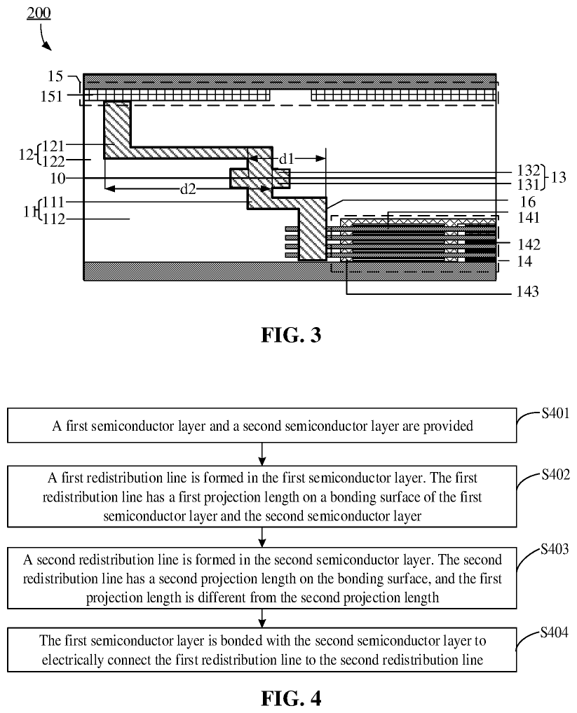

FIG. 3 is a schematic structural diagram of another semiconductor structure according to an embodiment of the disclosure. As illustrated in FIG. 3, the semiconductor structure 200 provided in the embodiment of the disclosure includes a first semiconductor layer 11 and a second semiconductor layer 12 bonded to each other. The first semiconductor layer 11 includes a first redistribution line 111, and the first redistribution line 111 has a first projection length d1 on a bonding surface 10 of the first semiconductor layer 11 and the second semiconductor layer 12. The second semiconductor layer 12 includes a second redistribution line 121, and the second redistribution line 121 has a second projection length d2 on the bonding surface 10. The first projection length d1 is different from the second projection length d2. The first redistribution line 111 is electrically connected to the second redistribution line 121.

In the embodiment of the disclosure, the first semiconductor layer 11 may include a first dielectric layer 112, and the first redistribution line 111 is located within the first dielectric layer 112. The second semiconductor layer 12 may include a second dielectric layer 122, and the second redistribution line 121 is located within the second dielectric layer 122.

With continued reference to FIG. 3, the first semiconductor layer 11 may further include a first metal pad 131 connected to the first redistribution line 111, and the second semiconductor layer 12 may further include a second metal pad 132 connected to the second redistribution line 121. The first redistribution line 111 is electrically connected to the second redistribution line 121 through the first metal pad 131 and the second metal pad 132.

With continued reference to FIG. 3, the first semiconductor layer 11 further includes a memory array 14, and the memory array 14 includes multiple wordlines 141 (i.e. a gate-all-around structure) and multiple bitlines (not illustrated in FIG. 3). Each of the multiple wordlines 141 is electrically connected to a respective one of multiple first redistribution lines 111, and each of the multiple bitlines is electrically connected to a respective one of the multiple first redistribution lines 111.

In some embodiments, the memory array 14 included in the first semiconductor layer 11 may have a 3D semiconductor structure. For example, the memory array 14 may include multiple wordlines which extend in a direction parallel to a surface of a substrate and present a ladder shape in a direction perpendicular to the surface of the substrate. For example, the wordlines may have a layer-by-layer decreasing length from bottom to top in the direction perpendicular to the surface of the substrate. The memory array 14 may further include bitlines which extend in the direction perpendicular to the surface of the substrate. Or, the memory array 14 may include multiple bitlines which extend in the direction parallel to the surface of the substrate and present a ladder shape in the direction perpendicular to the surface of the substrate. For example, the bitlines may have a layer-by-layer decreasing length from bottom to top in the direction perpendicular to the surface of the substrate. The memory array 14 may further include wordlines which extend in the direction perpendicular to the surface of the substrate. As illustrated in FIG. 1B, for example, the bonding pads 13a, 13b, 13c, 13d and 13e are configured to connect the bitlines extending in the direction perpendicular to the surface of the substrate and included in the memory array of the first semiconductor layer, and the bonding pads 13f, 13g, 13h, 13i and 13j are configured to connect the wordlines extending in the direction parallel to the surface of the substrate and included in the memory array of the first semiconductor layer.

In some embodiments, the memory array 14 may further include multiple transistors, multiple capacitors 142, and support structures 143 configured to support the multiple transistors and the multiple capacitors 142.

In the embodiments of the disclosure, a material of the bitline may be one or a combination of conductive materials such as polysilicon, metal silicide, conductive metal nitride (e.g. titanium nitride, tantalum nitride, tungsten nitride, etc.) and metals (e.g. tungsten, titanium, tantalum, etc.).

In some embodiments, the second semiconductor layer 12 includes a peripheral circuit 15, and the second redistribution lines 121 are electrically connected to the peripheral circuit 15.

In some embodiments, the peripheral circuit 15 may include a sense amplifier located in an active area 151 of the peripheral circuit. The sense amplifier is configured to sense a voltage difference between the bitline and a complementary bitline, and to amplify the voltage difference to a recognizable logic level, so that data may be correctly interpreted by a logic unit outside a memory device, thereby controlling a memory unit to store data into a corresponding capacitor and/or read data from the corresponding capacitor. With continued reference to FIG. 3, the second redistribution line 121 is connected to the active area 151.

In other embodiments, the peripheral circuit 15 may further include a row decoder, a column decoder, an input/output controller, a multiplexer, or the like.

In some embodiments, with continued reference to FIG. 3, each of the multiple wordlines 141 is electrically connected to the peripheral circuit 15 through a respective one of the first redistribution lines 111 and a respective one of the second redistribution lines 121, and each of the multiple bitlines (not illustrated in FIG. 3) is electrically connected to the peripheral circuit 15 through a respective one of the first redistribution lines 111 and a respective one of the second redistribution lines 121.

It should be noted that in the embodiments of the disclosure, the wordlines have a ladder-shape structure.

In some embodiments, with continued reference to FIG. 3, the semiconductor structure 200 further includes a barrier layer 16. The barrier layer 16 is located between the first redistribution lines 111 and the first dielectric layer 112, between the second redistribution lines 121 and the second dielectric layer 122, between the bonding pads 13 and the first dielectric layer 112, and between the bonding pads 13 and the second dielectric layer 122.

In the embodiments of the disclosure, a material of the barrier layer 16 may be titanium nitride, tantalum nitride, cobalt nitride, nickel nitride or tungsten nitride. In the embodiments of the disclosure, the material of the barrier layer 16 is titanium nitride, which has good barrier characteristics and adhesion characteristics and may effectively block diffusion of materials of the first redistribution lines and materials of the second redistribution lines.

In the embodiments of the disclosure, semiconductor layers are electrically connected by bonding. Since metal pads used for bonding have large areas, a problem of an electric connection failure between two semiconductor layers which is caused by a misalignment due to small electric connection points between the two semiconductor layers, may be avoided, thereby improving yield rate of semiconductor manufacturing.

Embodiments of the disclosure also provide a method for forming a semiconductor structure. FIG. 4 is a schematic flowchart of a method for forming a semiconductor structure according to an embodiment of the disclosure. As illustrated in FIG. 4, the method for forming the semiconductor structure includes the following operations S401 to S404.

In operation S401, a first semiconductor layer and a second semiconductor layer are provided.

In operation S402, a first redistribution line is formed in the first semiconductor layer. The first redistribution line has a first projection length on a bonding surface of the first semiconductor layer and the second semiconductor layer.

In operation S403, a second redistribution line is formed in the second semiconductor layer. The second redistribution line has a second projection length on the bonding surface, and the first projection length is different from the second projection length.

In operation S404, the first semiconductor layer is bonded with the second semiconductor layer to electrically connect the first redistribution line to the second redistribution line.

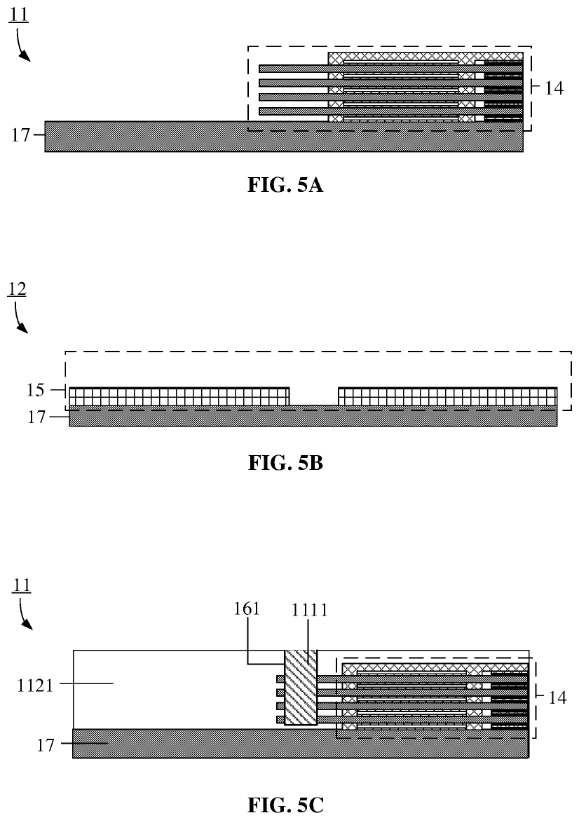

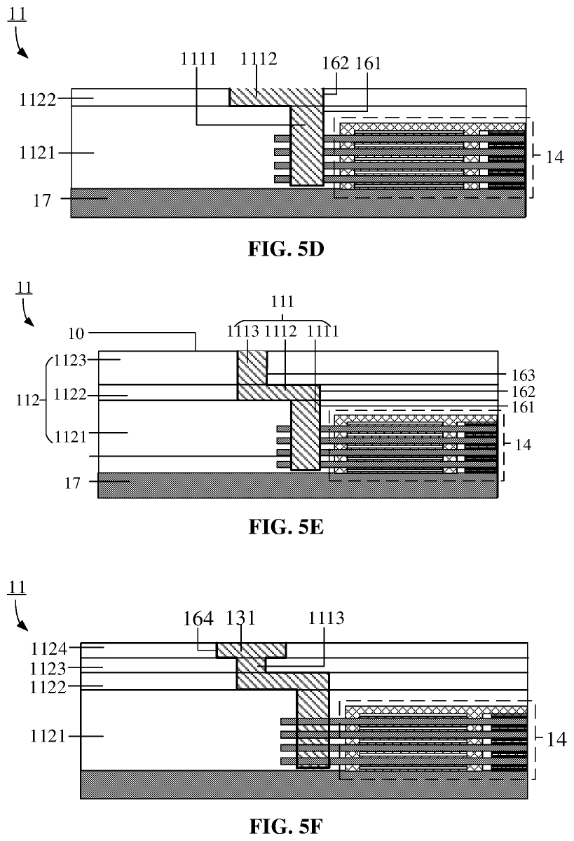

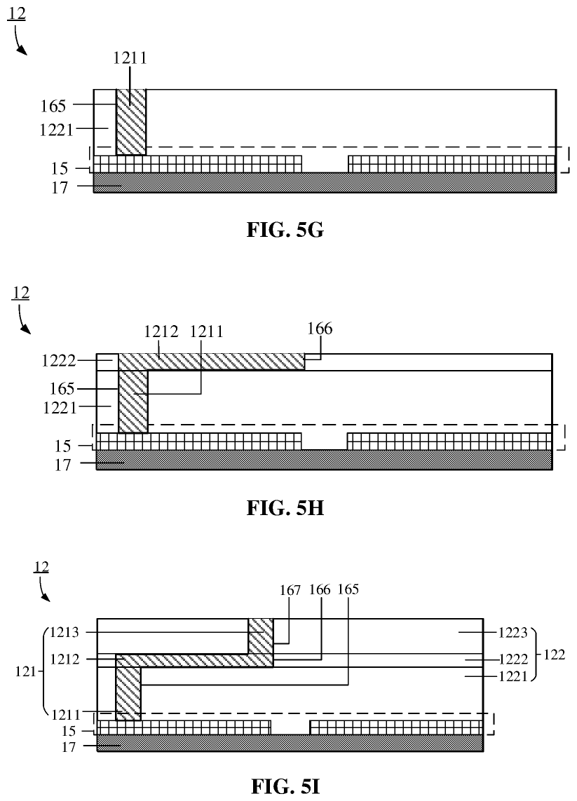

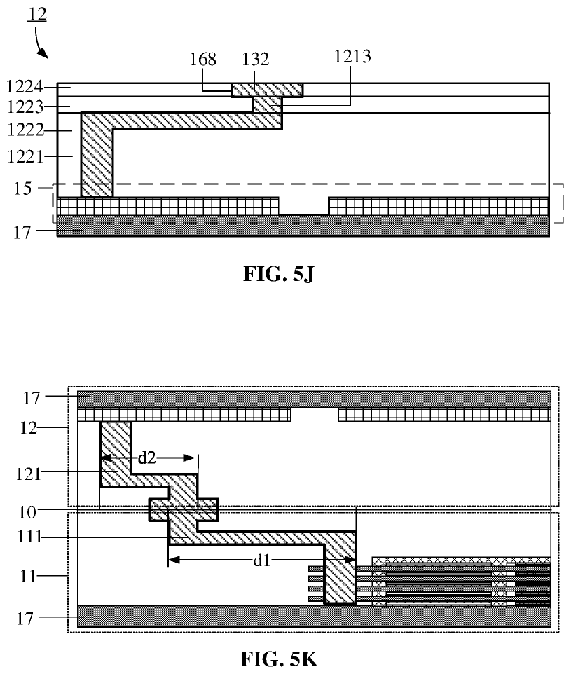

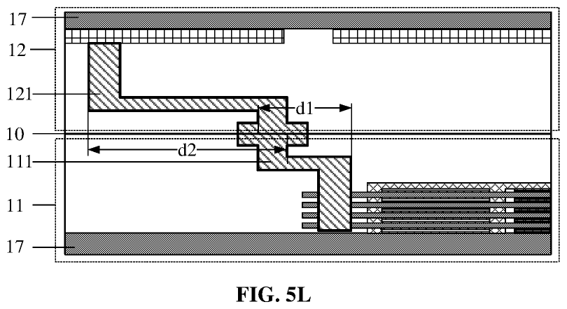

FIGS. 5A to 5L are schematic diagrams of a process for forming a semiconductor structure according to an embodiment of the disclosure. Schematic diagrams of the process for forming the semiconductor structure provided in the embodiments of the disclosure will be further described in detail below with reference to FIGS. 5A to 5L.

Firstly, with reference to FIGS. 5A and 5B, the operation S401 is performed so as to provide the first semiconductor layer 11 and the second semiconductor layer 12. The first semiconductor layer 11 includes a substrate 17 and a memory array 14 located on a surface of the substrate 17, and the second semiconductor layer 12 includes a substrate 17 and a peripheral circuit 15 located on a surface of the substrate 17.

In the embodiment of the disclosure, the substrate 17 may be a silicon substrate, a silicon-on-insulator substrate, or the like. The substrate may also include other semiconductor elements, or may include semiconductor compounds such as silicon carbide (SiC), gallium arsenide (GaAs), gallium phosphide (GaP), indium phosphide (InP), indium arsenide (InAs), or indium antimonide (InSb), or may include other semiconductor alloys such as gallium arsenide phosphide (GaAsP), indium aluminum arsenide (AlInAs), gallium aluminum arsenide (AlGaAs), indium gallium arsenide (GaInAs), indium gallium phosphide (GaInP), and/or indium gallium arsenide phosphide (GaInAsP) or combinations thereof.

Next, with reference to FIG. 5C to FIG. 5E, the operation S402 is performed so as to form a first redistribution line 111 in the first semiconductor layer 11. The first redistribution line 111 has a first projection length d1 on a bonding surface 10 of the first semiconductor layer 11 and the second semiconductor layer 12.

In some embodiments, the first redistribution line 111 may be formed by the following operations. A first dielectric layer 112 is formed on a surface of the substrate 17 of the first semiconductor layer 11. The first dielectric layer 112 is etched to form a first etching trench. The first etching trench is filled with metal material to form the first redistribution line 111.

Firstly, with reference to FIG. 5C, a first initial dielectric layer 1121 is formed on a surface of the substrate 17 of the first semiconductor layer 11. The first initial dielectric layer 1121 is etched to form a first trench (not illustrated in FIG. 5C). The first trench exposes wordlines or bitlines in the memory array 14. An inner wall of the first trench is filled with a barrier material to form a first barrier layer 161. A surface of the first barrier layer 161 is filled with a metal material to form a first wiring 1111. The first trench is filled up with the first wiring 1111. Secondly, with reference to FIG. 5D, a second initial dielectric layer 1122 is formed on a surface of the first initial dielectric layer 1121. The second initial dielectric layer 1122 is etched to form a second trench (not illustrated in FIG. The second trench exposes the first wiring 1111. An inner wall of the second trench is filled with a barrier material to form a second barrier layer 162. A surface of the second barrier layer 162 is filled with a metal material to form a second wiring 1112. The second trench is filled up with the second wiring 1112. Finally, with reference to FIG. 5E, a third initial dielectric layer 1123 is formed on a surface of the second initial dielectric layer 1122. The third initial dielectric layer 1123 is etched to form a third trench (not illustrated in FIG. 5E). The third trench exposes the second wiring 1112. An inner wall of the third trench is filled with a barrier material to form a third barrier layer 163. A surface of the third barrier layer 163 is filled with a metal material to form a third wiring 1113. The third trench is filled up with the third wiring 1113. The first initial dielectric layer 1121, the second initial dielectric layer 1122 and the third initial dielectric layer 1123 constitute the first dielectric layer 112. The first wiring 1111, the second wiring 1112 and the third wiring 1113 constitute the first redistribution line 111.

In some embodiments, with reference to FIG. 5F, the method for forming the semiconductor structure further includes the following operation. A first metal pad 131 electrically connected to the first redistribution line 111 is formed.

As illustrated in FIG. 5F, a fourth initial dielectric layer 1124 is formed on a surface of the third initial dielectric layer 1123. The fourth initial dielectric layer 1124 is etched to form a first metal pad trench (not illustrated in FIG. 5F). The first metal pad trench exposes the third wiring 1113, and an opening size of the first metal pad trench is larger than an opening size of the third trench. An inner wall of the first metal pad trench is filled with a barrier material to form a fourth barrier layer 164. A surface of the fourth barrier layer 164 is filled with a metal material to form the first metal pad 131. A top surface of the first metal pad 131 is flush with a top surface of the fourth initial dielectric layer 1124.

In the embodiments of the disclosure, the barrier material may be titanium, tungsten, tantalum, platinum metal alloys, such as tantalum nitride, and the metal material may be copper, aluminum, copper-aluminum alloy or tungsten.

Next, with reference to FIG. 5G to FIG. 5I, the operation S403 is performed to form a second redistribution line 121 in the second semiconductor layer 12. The second redistribution line 121 has a second projection length d2 on the bonding surface, and the first projection length d1 is different from the second projection length d2.

In some embodiments, the second redistribution line 121 is formed by the following operations. A second dielectric layer 122 is formed on a surface of the substrate 17 of the second semiconductor layer. The second dielectric layer 122 is etched to form a second etching trench. The second etching trench is filled with metal material to form the second redistribution line 121.

Firstly, with reference to FIG. 5G, a fifth initial dielectric layer 1221 is formed on a surface of the substrate 17 of the second semiconductor layer 12. The fifth initial dielectric layer 1221 is etched to form a fourth trench (not illustrated in FIG. 5G). The fourth trench exposes an active area of the peripheral circuit 15. An inner wall of the fourth trench is filled with a barrier material to form a fifth barrier layer 165. A surface of the fifth barrier layer 165 is filled with a metal material to form a fourth wiring 1211. The fourth trench is filled up with the fourth wiring 1211. Secondly, with reference to FIG. 5H, a sixth initial dielectric layer 1222 is formed on a surface of the fifth initial dielectric layer 1221. The sixth initial dielectric layer 1222 is etched to form a fifth trench (not illustrated in FIG. 5H). The fifth trench exposes the fourth wiring 1211. An inner wall of the fifth trench is filled with a barrier material to form a sixth barrier layer 166. A surface of the sixth barrier layer 166 is filled with a metal material to form a fifth wiring 1212. The fifth trench is filled with the fifth wiring 1212. Finally, with reference to FIG. 5I, a seventh initial dielectric layer 1223 is formed on a surface of the sixth initial dielectric layer 1222. A surface of the seventh initial dielectric layer 1223 is etched to form a sixth trench (not illustrated in FIG. 5I). The sixth trench exposes the fifth wiring 1212. An inner wall of the sixth trench is filled with a barrier material to form a seventh barrier layer 167. A surface of the seventh barrier layer 167 is filled with a metal material to form a sixth wiring 1213. The sixth trench is filled up with the sixth wiring 1213. The fifth initial dielectric layer 1221, the sixth initial dielectric layer 1222 and the seventh initial dielectric layer 1223 constitute the second dielectric layer 122. The fourth wiring 1211, the fifth wiring 1212 and the sixth wiring 1213 constitute the second redistribution line 121.

In the embodiments of the disclosure, the barrier material may be titanium, tungsten, tantalum, platinum metal alloys, such as tantalum nitride, and the metal material may be copper, aluminum, copper-aluminum alloy or tungsten.

In some embodiments, with reference to FIG. 5J, the method for forming the semiconductor structure further includes the following operation. A second metal pad 132 electrically connected to the second redistribution line 121 is formed.

As illustrated in FIG. 5J, an eighth initial dielectric layer 1224 is formed on a surface of the seventh initial dielectric layer 1223. The eighth initial dielectric layer 1224 is etched to form a second metal pad trench (not illustrated in FIG. 5J). The second metal pad trench exposes the sixth wiring 1213, and an opening size of the second metal pad trench is larger than an opening size of the sixth trench. An inner wall of the second metal pad trench is filled with a barrier material to form an eighth barrier layer 168. A surface of the eighth barrier layer 168 is filled with a metal material to form the second metal pad 132. A top surface of the second metal pad 132 is flush with a surface of the eighth initial dielectric layer 1224.

With continued reference to FIG. 5C to FIG. 5J, in the embodiments of the disclosure, the first barrier layer 161, the second barrier layer 162, the third barrier layer 163, the fourth barrier layer 164, the fifth barrier layer 165, the sixth barrier layer 166, the seventh barrier layer 167 and the eighth barrier layer 168 constitute the barrier layer 16.

In the embodiments of the disclosure, materials of the first metal pad 131 and the second metal pad 132 may be any conductive metal material such as copper, aluminum, copper-aluminum alloy or tungsten. The first metal pad 131 and the second metal pad 132 are configured to electrically connect the first redistribution line 111 to the second redistribution line 121. In some embodiments, an isolation material may also be filled between adjacent metal pads in order to reduce short-circuit between adjacent metal pads.

Next, with reference to FIGS. 5K and 5L, the operation S404 is performed so as to bond the first semiconductor layer 11 with the second semiconductor layer 12, to electrically connect the first redistribution line 111 to the second redistribution line 121.

In some embodiments, the operation of bonding the first semiconductor layer 11 with the second semiconductor layer 12 to electrically connect the first redistribution line 111 to the second redistribution line 121, includes the following operations.

Surface activation treatment is performed on a first surface of the first semiconductor layer 11 exposing the first metal pad 131 and a second surface of the second semiconductor layer 12 exposing the second metal pad 132.

In the embodiments of the disclosure, a purpose of the activation treatment is to realize cleaning of surfaces of the first semiconductor layer 11 and the second semiconductor layer 12 to remove metal oxides, chemicals, particles or other impurities on the surfaces of the first semiconductor layer 11 and the second semiconductor layer 12.

In the embodiments of the disclosure, the first surface is attached to the second surface with the first metal pad 131 being aligned to the second metal pad 132 face to face, and the first semiconductor layer 11 and the second semiconductor layer 12 are annealed.

In the embodiments of the disclosure, defects in the first semiconductor layer and the second semiconductor layer are reduced by annealing the first semiconductor layer and the second semiconductor layer.

In the embodiments of the disclosure, with reference to FIGS. 5K and 5L, the first redistribution line 111 has a first projection length d1 on a bonding surface 10 of the first semiconductor layer 11 and the second semiconductor layer 12. The second redistribution line 121 has a second projection length d2 on the bonding surface 10 of the first semiconductor layer 11 and the second semiconductor layer 12. The first projection length d1 is different from the second projection length d2. For example, the first projection length d1 is larger than the second projection length d2 (as illustrated in FIG. 5K), or the first projection length d1 is smaller than the second projection length d2 (as illustrated in FIG. 5L).

According to the method for forming the semiconductor structure provided in the embodiments of the disclosure, a first metal pad is formed on a surface of the first semiconductor, and a second metal pad is formed on a surface of the second semiconductor. The first semiconductor layer and the second semiconductor layer have large areas, a problem of an electric connection failure between two semiconductor layers which is caused by a misalignment due to small electric connection points between the two semiconductor layers, may be avoided, thereby improving yield rate of semiconductor manufacturing. Furthermore, in the embodiments of the disclosure, a distance between the metal pads may be increased by forming different projection lengths of the first and second redistribution lines, thereby reducing a parasitic capacitance of the formed semiconductor structure and improving performance of the semiconductor structure.

In the embodiments of the disclosure, it should be understood that the disclosed device and method may be implemented in a non-target way. The device embodiments as described above are merely illustrative. For example, partitioning of the unit is merely a partitioning of logical function. Other partitioning modes may be adopted in a practical implementation. For example, multiple units or components may be combined or integrated into another system, or some features may be ignored or may not be executed. Furthermore, coupling, or the direct coupling exists between the components shown or discussed.

The features disclosed in several method or device embodiments of the disclosure may be arbitrarily combined without conflict, to obtain new method or device embodiments.

The foregoing descriptions are merely some embodiments of the disclosure, however, the scope of protection of the disclosure is not limited thereto. Any change or replacement readily contemplated by those skilled in the art within the technical scope disclosed in the disclosure shall fall within the scope of protection of the disclosure. Accordingly, the scope of protection of the disclosure shall be subject to the scope of protection of the claims.

In the embodiments of the disclosure, semiconductor layers are electrically connected by bonding. Since metal pads used for bonding have large areas, a problem of an electric connection failure between two semiconductor layers which is caused by a misalignment due to small electric connection points between the two semiconductor layers, may be avoided, thereby improving yield rate of semiconductor manufacturing. Furthermore, in the embodiments of the disclosure, a distance between the metal pads may be increased by providing different projection lengths of redistribution lines in two semiconductor layers, thereby reducing a parasitic capacitance and improving performance of the semiconductor structure.

What is claimed is:

1. A semiconductor structure, comprising: a first semiconductor layer and a second semiconductor layer bonded to each other,
wherein the first semiconductor layer comprises a first redistribution line, and the first redistribution line has a first projection length on a bonding surface of the first semiconductor layer and the second semiconductor layer,
wherein the second semiconductor layer comprises a second redistribution line, the second redistribution line has a second projection length on the bonding surface, and the first projection length is different from the second projection length, and
wherein the first redistribution line is electrically connected to the second redistribution line.

2. The semiconductor structure of claim 1, wherein the first semiconductor layer comprises a plurality of first redistribution lines, and the second semiconductor layer comprises a plurality of second redistribution lines, and
wherein projection lengths of any two adjacent first redistribution lines on the bonding surface are different, or projection lengths of any two adjacent second redistribution lines on the bonding surface are different.

3. The semiconductor structure of claim 2, wherein each of the plurality of first redistribution lines is electrically connected to a respective one of the plurality of second redistribution lines, and a sum of projection lengths of each of the plurality of first redistribution lines and a respective one of the plurality of second redistribution lines on the bonding surface has a same value.

4. The semiconductor structure of claim 3, wherein the plurality of first redistribution lines are circularly arranged in a preset arrangement manner, and
wherein the preset arrangement manner comprises: first projection lengths of the plurality of first redistribution lines being sequentially increased, the first projection lengths being sequentially decreased, the first projection lengths being firstly increased and then decreased, and the first projection lengths being firstly decreased and then increased.

5. The semiconductor structure of claim 4, wherein as the first projection lengths of the plurality of first redistribution lines on the bonding surface are sequentially decreased, second projection lengths of the plurality of second redistribution lines corresponding to the plurality of first redistribution lines on the bonding surface are sequentially increased.

6. The semiconductor structure of claim 4, wherein as the first projection lengths of the plurality of first redistribution lines on the bonding surface are sequentially increased, second projection lengths of the plurality of second redistribution lines corresponding to the plurality of first redistribution lines on the bonding surface are sequentially decreased.

7. The semiconductor structure of claim 4, wherein as the first projection lengths of the plurality of first redistribution lines on the bonding surface are firstly increased and then decreased, second projection lengths of the plurality of second redistribution lines corresponding to the plurality of first redistribution lines on the bonding surface are firstly decreased and then increased.

8. The semiconductor structure of claim 4, wherein as the first projection lengths of the plurality of first redistribution lines on the bonding surface are firstly decreased and then increased, second projection lengths of the plurality of second redistribution lines corresponding to the plurality of first redistribution lines on the bonding surface are firstly increased and then decreased.

9. The semiconductor structure of claim 2, wherein the first semiconductor layer further comprises a first metal pad connected to the first redistribution line, and the second semiconductor layer further comprises a second metal pad connected to the second redistribution line, and
wherein the first redistribution line is electrically connected to the second redistribution line through the first metal pad and the second metal pad.

10. The semiconductor structure of claim 9, wherein each of a plurality of first metal pads is bonded with a respective one of a plurality of second metal pads to form a respective one of a plurality of bonding pads, and the plurality of bonding pads are distributed in a ladder shape on the bonding surface.

11. The semiconductor structure of claim 10, wherein the first semiconductor layer comprises a memory array, and the memory array comprises a plurality of wordlines and a plurality of bitlines, and
wherein each of the plurality of wordlines is electrically connected to a respective one of the plurality of first redistribution lines, and each of the plurality of bitlines is electrically connected to a respective one of the plurality of first redistribution lines.

12. The semiconductor structure of claim 11, wherein the second semiconductor layer comprises a peripheral circuit, and the plurality of second redistribution lines are electrically connected to the peripheral circuit.

13. The semiconductor structure of claim 12, wherein each of the plurality of wordlines is electrically connected to the peripheral circuit through a respective one of the plurality of first redistribution lines and a respective one of the plurality of second redistribution lines, and each of the plurality of bitlines is electrically connected to the peripheral circuit through a respective one of the plurality of first redistribution lines and a respective one of the plurality of second redistribution lines.

14. The semiconductor structure of claim 13, wherein the first semiconductor layer comprises a first dielectric layer, and the plurality of first redistribution lines are located within the first dielectric layer,
wherein the second semiconductor layer comprises a second dielectric layer, and the plurality of second redistribution lines are located within the second dielectric layer,
wherein the semiconductor structure further comprises a barrier layer, and
wherein the barrier layer is located between the plurality of first redistribution lines and the first dielectric layer, between the plurality of second redistribution lines and the second dielectric layer, between the plurality of bonding pads and the first dielectric layer, and between the plurality of bonding pads and the second dielectric layer.

15. A method for forming a semiconductor structure, comprising:
providing a first semiconductor layer and a second semiconductor layer;
forming a first redistribution line in the first semiconductor layer, wherein the first redistribution line has a first projection length on a bonding surface of the first semiconductor layer and the second semiconductor layer;
forming a second redistribution line in the second semiconductor layer, wherein the second redistribution line has a second projection length on the bonding surface, and the first projection length is different from the second projection length; and
bonding the first semiconductor layer with the second semiconductor layer to electrically connect the first redistribution line to the second redistribution line.

16. The method of claim 15, wherein the first redistribution line is formed by:
forming a first dielectric layer on a surface of a substrate of the first semiconductor layer;
etching the first dielectric layer to form a first etching trench; and
filling the first etching trench with metal material to form the first redistribution line.

17. The method of claim 15, wherein the second redistribution line is formed by:
forming a second dielectric layer on a surface of a substrate of the second semiconductor layer;
etching the second dielectric layer to form a second etching trench; and
filling the second etching trench with metal material to form the second redistribution line.

18. The method of claim 15, further comprising:
forming a first metal pad electrically connected to the first redistribution line; and
forming a second metal pad electrically connected to the second redistribution line.

19. The method of claim 16, further comprising:
forming a first metal pad electrically connected to the first redistribution line; and
forming a second metal pad electrically connected to the second redistribution line. The method of claim 18, wherein bonding the first semiconductor layer with the second semiconductor layer to electrically connect the first redistribution line to the second redistribution line comprises:
performing surface activation treatment on a first surface of the first semiconductor layer exposing the first metal pad and a second surface of the second semiconductor layer exposing the second metal pad;
attaching the first surface to the second surface with the first metal pad being aligned to the second metal pad face to face; and
annealing the first semiconductor layer and the second semiconductor layer.
